(19) United States
(12) Patent Application Publication
(10) Pub. No.: US 2022/0229595 A1
(43) Pub. Date: Jul. 21, 2022

(54) CONTROLLER AND OPERATION METHOD THEREOF

(71) Applicant: SK hynix Inc., Gyeonggi-do (KR)

(72) Inventors: Ji Hoon LEE, Gyeonggi-do (KR); Chung Un NA, Gyeonggi-do (KR)

(21) Appl. No.: 17/358,936

(22) Filed: Jun. 25, 2021

(30) Foreign Application Priority Data
Jan. 20, 2021 (KR) 10-2021-0007800

(51) Int. Cl. G06F 3/06

(52) U.S. Cl. CPC G06F 3/0659; G06F 3/0679; G06F 3/0604

(57) ABSTRACT

Provided is a controller which controls a plurality of memory dies. The controller may include: a processor suitable for generating interleaved read commands based on read requests from a host; a memory interface suitable for acquiring the read commands and a host-requested order of the read commands from the processor, controlling page read operations on the plurality of memory dies in response to the read commands, and acquiring data chunks corresponding to read requests from memory dies whose page read operations are completed, according to the host-requested order; and a host interface suitable for providing the host with responses to the read requests according to the order in which the data chunks are acquired.

### CROSS-REFERENCE TO RELATED APPLICATION

This application claims priority under 35 U.S.C. § 119 to Korean Patent Application No. 10-2021-0007800 filed on Jan. 20, 2021, which is incorporated herein by reference in its entirety.

### BACKGROUND

### 1. Field

Embodiments of the present disclosure relate to a controller and an operation method thereof.

### 2. Discussion of the Related Art

The computer environment paradigm has been transitioning to ubiquitous computing, which enables computing systems to be used anytime and anywhere. As a result, use of portable electronic devices such as mobile phones, digital cameras, and laptop computers has rapidly increased. These portable electronic devices generally use a memory system having one or more memory devices for storing data. A memory system may be used as a main memory device or an auxiliary memory device of a portable electronic device.

Since memory systems have no moving parts, memory systems provide advantages such as excellent stability and durability, high information access speed, and low power consumption. Examples of memory systems having such advantages include universal serial bus (USB) memory devices, memory cards having various interfaces, and solid state drives (SSDs).

### SUMMARY

Various embodiments of the present disclosure are directed to a controller capable of improving the throughput of a memory system by reducing latency for a read request, and an operation method thereof.

In an embodiment of the present disclosure, there is provided a controller which controls a plurality of memory dies. The controller may include: a processor suitable for generating interleaved read commands based on read requests from a host; a memory interface suitable for acquiring the read commands and a host-requested order of the read commands from the processor, controlling page read operations on the plurality of memory dies in response to the read commands, and acquiring data chunks corresponding to read requests from memory dies whose page read operations are completed, according to the host-requested order; and a host interface suitable for providing the host with responses to the read requests according to the order in which the data chunks are acquired.

The operation of the memory interface to acquire the data chunks and the operation of the host interface to provide the responses to the read requests may be performed in parallel.

The processor may generate the read commands by adjusting a processing order of the read requests and translating the read requests into read commands according to the adjusted order.

The processor queues read requests from the host interface into a request queue, determines the order in which the read requests are queued, as a host-requested order, and provides the read requests and the host-requested order to the memory interface.

The memory interface may include a plurality of command queues corresponding to the plurality of memory dies, and queues the read commands into the plurality of command queues based on memory dies in which the read commands are to be respectively processed.

The memory interface may provide page read commands to the plurality of memory dies in a predetermined order according to identifiers of the plurality of memory dies, such that the page read operations of the plurality of memory dies are performed at the same time.

The memory interface may provide a state read command to the memory dies when a predetermined time has elapsed after the page read commands are provided to the plurality of memory dies, and determine whether the page read operations are completed, based on responses of the memory dies to the state read command.

The host interface may count the host-requested order of the read requests, may adjust a processing order of the read requests based on the priorities of the read requests, and may provide the processor with the host-requested order and the read requests whose processing order is adjusted.

The processor may queue the read requests into a plurality of request queues based on the priorities, and provide the host-requested order from the host interface to the memory interface together when providing the memory interface with read commands queued in the plurality of request queues.

In an embodiment of the present disclosure, there is provided an operation method of a controller which controls a plurality of memory dies. The operation method may include: generating host-requested order information of read requests from a host based on the read requests; generating interleaved read commands based on the read requests; controlling page read operations on the plurality of memory dies based on the read commands; acquiring data chunks corresponding to the read requests from memory dies whose page read operations are completed, according to the host-requested order; and providing the host with responses to the read requests according to the order in which the data chunks are acquired.

The acquiring of the data chunks and the providing the host with the responses to the read requests may be performed in parallel.

The generating the read commands may include: adjusting a processing order of the read requests; and translating the read requests into read commands according to the adjusted order.

The operation method may further include: queuing read requests from the host into a request queue; and determining the order in which the read requests are queued, as the host-requested order.

The operation method may further include queuing read commands into a plurality of command queues corresponding to the plurality of memory dies, based on memory dies in which the read commands are to be respectively processed.

The controlling the page read operations may include providing page read commands to the plurality of memory dies in a predetermined order according to the identifiers of the plurality of memory dies, such that the page read operations of the plurality of memory dies are performed at the same time.

The operation method may further include: providing a state read command to the memory dies when a predetermined time has elapsed after the page read commands were provided to the plurality of memory dies; and determining whether the page read operations are completed, based on responses of the memory dies to the state read command.

The operation method may further include adjusting the processing order of the read requests based on the priorities of the read requests, wherein the adjusting the processing order is performed after the generating of the host-requested order information.

The operation method may further include queuing the read requests into a plurality of request queues based on the priorities.

In an embodiment of the present disclosure, a system includes: a host; and a memory system coupled to the host and including a controller and a plurality of dies coupled to the controller, wherein the controller is configured to: receive, from the host, a plurality of read requests; generate interleaved read commands based on the plurality of read requests and order information indicating a requested order of the plurality of read requests; control the plurality of memory dies to perform page read operations in response to the interleaved read commands; receive data chunks from the plurality of memory dies based on the order information when the page read operations are completed; and provide, to the host, the data chunks based on the order information.

In accordance with embodiments of the present disclosure, it is possible to provide a controller capable of improving the throughput of a memory system by reducing latency for a read request, and an operation method thereof.

### BRIEF DESCRIPTION OF THE DRAWINGS

FIG. 1 is a diagram schematically illustrating an example of a data processing system including a memory system in accordance with an embodiment of the present disclosure.

FIG. 2 is a circuit diagram illustrating a configuration of a memory die in accordance with an embodiment of the present disclosure.

FIG. 3 is a diagram for describing signals which a controller and a memory device exchange with each other in accordance with an embodiment of the present disclosure.

FIG. 4 is a diagram illustrating first to fourth memory dies included in the memory device of FIG. 3 in accordance with an embodiment of the present disclosure.

FIG. 5 is a diagram illustrating an architecture of a controller in accordance with embodiments of the present disclosure.

FIG. 6 is a diagram for describing a controller in accordance with a first embodiment of the present disclosure.

FIG. 7 is a diagram illustrating an operation of a data processing system in accordance with a first embodiment of the present disclosure.

FIG. 8 is a timing diagram for describing an operation of a memory system in accordance with a first embodiment of the present disclosure.

FIG. 9 is a diagram for describing a controller in accordance with a second embodiment of the present disclosure.

### DETAILED DESCRIPTION

Hereafter, preferred embodiments of the present disclosure will be described with reference to the accompanying drawings.

However, the present disclosure is not limited to the following embodiments, but may be implemented in various manners, and these embodiments disclosed herein are provided so that this disclosure will be thorough and complete and the scope of the present disclosure will be fully conveyed to those skilled in the art.

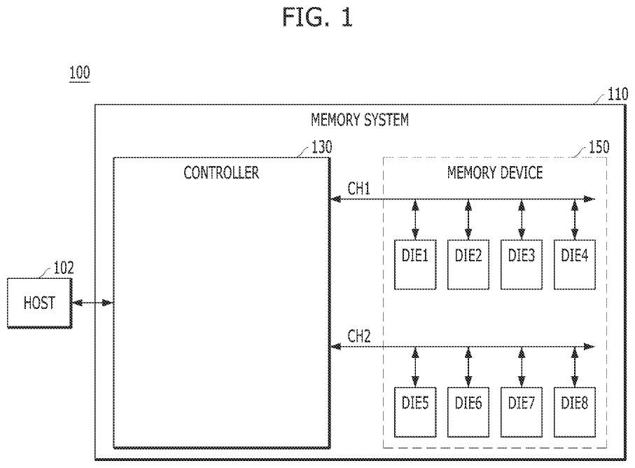

FIG. 1 is a block diagram illustrating a data processing system 100 in accordance with an embodiment of the present invention.

Referring to FIG. 1, the data processing system 100 may include a host 102 operatively coupled to a memory system 110.

The host 102 may include any of various portable electronic devices such as a mobile phone, MP3 player and laptop computer, or any of various non-portable electronic devices such as a desktop computer, a game machine, a television (TV), and a projector.

The host 102 may include at least one operating system (OS), which may manage and control overall functions and operations of the host 102, and provide operation between the host 102 and a user using the data processing system 100 or the memory system 110. The OS may support functions and operations corresponding to the use, purpose, and usage of a user. For example, the OS may be divided into a general OS and a mobile OS, depending on the mobility of the host 102. The general OS may be divided into a personal OS and an enterprise OS, depending on the environment of a user.

The memory system 110 may be embodied by various types of storage devices. Examples of such storage devices may include, but are not limited to, volatile memory devices such as a dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), a resistive RAM (RRAM or ReRAM) and a flash memory. The flash memory may have a 3-dimensional (3D) stack structure.

The memory system 110 may include a controller 130 and a memory device 150. The memory device 150 may store data for the host 102, and the controller 130 may control data storage into the memory device 150.

The controller 130 and the memory device 150 may be integrated into a single semiconductor device. For example, the controller 130 and the memory device 150 may be integrated as one semiconductor device to constitute a solid state drive (SSD). When the memory system 110 is used as an SSD, the operating speed of the host 102 connected to the memory system 110 can be improved. In addition, the controller 130 and the memory device 150 may be integrated as one semiconductor device to constitute a memory card. For example, the controller 130 and the memory device 150 may constitute a memory card such as a personal computer memory card international association (PCMCIA) card, compact flash (CF) card, smart media (SM) card, memory stick, multimedia card (MMC) including reduced size MMC (RS-MMC) and micro-MMC, secure digital (SD) card including mini-SD card, micro-SD card and SDHC card, or universal flash storage (UFS) device.

Non-limiting application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a group of nonvolatile memory devices and may retain data stored therein even though power is not supplied. The memory device 150 may store data provided from the host 102 through a program operation, and provide data stored therein to the host 102 through a read operation. The memory device 150 may include a plurality of memory blocks each of which may include a plurality of pages, and each of the pages may include a plurality of memory cells coupled to a word line. In an embodiment, the memory device 150 may be a group of flash memories. The flash memory may have a 3-dimensional (3D) stack structure.

The memory device 150 may include a plurality of memory dies, e.g., 8 memory dies DIE1 to DIE8. The memory dies DIE1 to DIE8 may be coupled to the controller 130 through a plurality of channels, e.g., two channels CH1 and CH2. In FIG. 1, the first to fourth memory dies DIE1 to DIE4 may be coupled to the first channel CH1, and the fifth to eighth memory dies DIE5 to DIE8 may be coupled to the second channel CH2.

By way of example, FIG. 1 illustrates a case in which eight memory dies DIE1 to DIE8 may be included in the memory device 150 and the memory device 150 and the controller 130 may be coupled through two channels CH1 and CH2. However, the number of memory dies included in the memory device 150 and the number of channels coupling the memory devices 150 and the controller 130 are not limited to the example of FIG. 1.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, program and erase operations of the memory device 150.

A write request or read request which the host 102 provides to the controller 130 may include a logical address used by the host 102. For example, the logical address may be a logical block address (LBA) used in a file system of an operating system of the host 102.

The memory device 150 may have a memory region identified by a physical address different from the logical address. For example, different physical addresses may be allocated to respective pages of the memory device 150. The controller 130 may generate map data by mapping a logical address into a physical address in order to control the memory device 150. The controller 130 may store map data in an internal memory thereof based on logical addresses, the map data indicating physical addresses corresponding to the logical addresses.

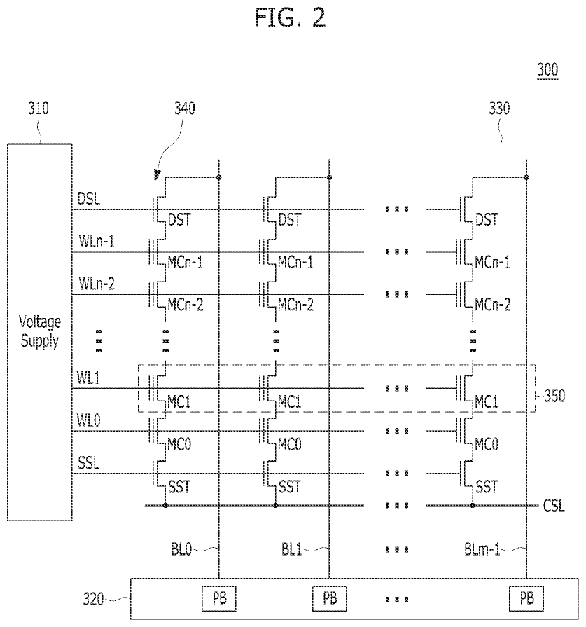

The memory dies DIE1 to DIE8 included in the memory device 150 are described in detail with reference to FIG. 2.

FIG. 2 is a circuit diagram illustrating a configuration of a memory die 300 in accordance with an embodiment of the present disclosure.

The memory die 300 illustrated in FIG. 2 may correspond to any of the memory dies DIE1 to DIE8 as described above with reference to FIG. 1. The memory die may include a voltage supply 310, a read and write (read/write) circuit 320 and a memory block 330. The memory die 300 may include a plurality of memory blocks, but FIG. 2 shows one memory block 330 as an example.

The memory block 330 may include a plurality of cell strings 340 coupled to a plurality of corresponding bit lines BL0 to BLm-1. The cell string 340 of each column may include one or more drain select transistors DST and one or more source select transistors SST. Between the drain and source select transistors DST and SST, a plurality of memory cells or memory cell transistors MC0 to MCn-1 may be coupled in series. In an embodiment, each of the memory cells MC0 to MCn-1 may be embodied by a multi-level cell (MLC) capable of storing data information of a plurality of bits. Each of the cell strings 340 may be electrically coupled to a corresponding bit line among the plurality of bit lines BL0 to BLm-1. For example, as illustrated in FIG. 2, the first cell string is coupled to the first bit line BL0, and the last cell string is coupled to the last bit line BLm-1. For reference, in FIG. 2, ‘DSL’ denotes a drain select line, ‘SSL’ denotes a source select line, and ‘CSL’ denotes a common source line.

Although FIG. 2 illustrates NAND flash memory cells, the invention is not limited in this way. It is noted that the memory cells may be NOR flash memory cells, or hybrid flash memory cells including two or more types of memory cells combined therein. Also, it is noted that the memory die 300 may be a flash memory device including a conductive floating gate as a charge storage layer or a charge trap flash (CTF) memory device including an insulation layer as a charge storage layer.

The memory die 300 may further include the voltage supply 310 which provides word line voltages including a program voltage, a read voltage and a pass voltage to supply to the word lines according to an operation mode. The voltage generation operation of the voltage supply 310 may be controlled by a control circuit (not illustrated). Under the control of the control circuit, the voltage supply 310 may select one of the memory blocks (or sectors) of the memory cell array, select one of the word lines of the selected memory block, and provide the word line voltages to the selected word line and the unselected word lines as may be needed.

The memory die 300 may include the read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers PB respectively corresponding to columns (or bit lines) or column pairs (or bit line pairs), and each of the page buffers PB may include a plurality of latches (not illustrated).

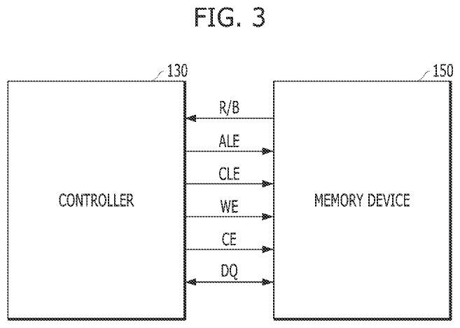

The memory cells of the memory block 330 may be coupled to a plurality of word lines WL0 to WLn-1. Memory cells coupled to one word line may be referred to as a physical page. By way of example, FIG. 3 illustrates a physical page 350 including the memory cells MC1 coupled to the word line WL1. The memory cells may be accessed on a page basis by the voltage supply 310 and the read/write circuit 320. FIG. 3 is a diagram for describing signals which the controller 130 and the memory device 150 exchange with each other in accordance with an embodiment of the present disclosure.

Referring to FIG. 3, the controller 130 may provide the memory device 150 with a chip enable signal CE, thereby selecting one memory device 150 among a plurality of memory devices that may be included in the memory system 110.

The controller 130 and the memory device 150 may exchange data signals DQ. The controller 130 may provide the memory device 150 with a command CMD, an address ADDR and data DATA through the data signal DQ, and the memory device 150 may provide the controller 130 with the data DATA through the data signal DQ. Whether a signal transmitted by the controller 130 through the data signal DQ is the command CMD, the address ADDR or the data DATA may be specified through a command latch enable signal CLE, an address latch enable signal ALE and a write enable signal WE.

The memory device 150 may provide the controller 130 with internal operation state information of the memory device 150 through a ready/busy signal R/B.

One channel may sequentially transfer commands to memory dies coupled to the channel, or sequentially transfer data from the memory dies to the controller 130. However, a plurality of memory dies receiving commands through a channel may perform command operations at the same time.

The controller 130 may interleave the commands for the plurality of memory dies, and provide the interleaved commands to the memory device 150. The operation of interleaving commands may include an operation of the controller 130 to decide a providing order of commands for controlling the plurality of memory dies to operate at the same time. Since the plurality of memory dies can operate at the same time based on the interleaved commands, the throughput of the memory system 110 may be improved.

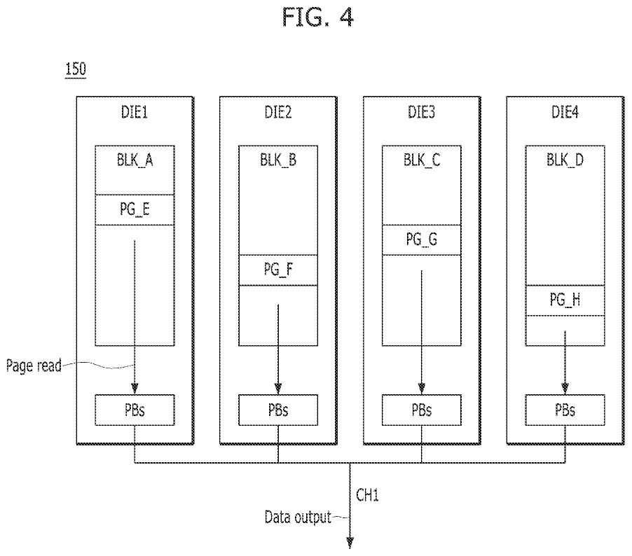

Hereafter, a read operation performed by a plurality of memory dies based on interleaved read commands may be referred to as an interleaved read operation. An interleaved read operation of the memory device 150 is described with reference to FIG. 4.

FIG. 4 is a diagram illustrating the first to fourth memory dies DIE1 to DIE4 included in the memory device 150 in accordance with an embodiment of the present disclosure.

The first to fourth memory dies DIE1 to DIE4 illustrated in FIG. 4 may correspond to the first to fourth memory dies DIE1 to DIE4 described with reference to FIG. 1. The first to fourth memory dies DIE1 to DIE4 may share the first channel CH1.

The read operation of the memory device 150 may include a page read operation and a data output operation.

The page read operation may include an operation of buffering data programmed in the memory block 330 into the page buffers PB by applying voltages to the bit lines BL0 to BLm-1 and the word lines WL0 to WLn-1 of the memory die 300. The data output operation may include an operation of outputting data buffered in the page buffers PB to the controller 130 through a channel.

The controller 130 may provide page read commands and data output commands to the memory device 150 in order to control the page read operations and the data output operations of the plurality of memory dies based on the interleaved read commands.

For example, the controller 130 may sequentially provide the page read commands for the first to fourth memory dies DIE1 to DIE4 through the first channel CH1 so that the page read operations of the first to fourth memory dies DIE1 to DIE4 may be simultaneously performed in the memory device 150.

The controller 130 may provide a page read command by specifying a block and page address of a target page to be read in each of the planes. In an example of FIG. 4, the controller 130 may sequentially provide a page read command for a page E (PG_E) of a block A (BLK_A) of the first memory die DIE1, a page read command for a page F (PG_F) of a block B (BLK_B) of the second memory die DIE2, a page read command for a page G (PG_G) of a block C (BLK_C) of the third memory die DIE3 and a page read command for a page H (PG_H) of a block D (BLK_D) of the fourth memory die DIE4.

The first to fourth memory dies DIE1 to DIE4 may simultaneously perform the page read operations in response to the page read commands. The data read from the first to fourth memory dies DIE1 to DIE4 may be buffered in the page buffers PBs included in each of the memory dies.

The controller 130 may provide state read commands to the first to fourth memory dies DIE1 to DIE4. The first to fourth memory dies DIE1 to DIE4 may provide to the controller 130 signals indicating whether the page read operations are completed in response to the state read commands. For example, each of the first to fourth memory dies DIE1 to DIE4 may provide a ready signal when the page read operation is completed, and may provide a busy signal when the page read operation is not completed.

The controller 130 may sequentially provide the data output commands to the first to fourth memory dies DIE1 to DIE4 when the page read operations of the first to fourth memory dies DIE1 to DIE4 are completed. The first to fourth memory dies DIE1 to DIE4 may sequentially output the data buffered in the page buffers PBs through the first channel CH1, in response to the data output commands.

As described with reference to FIGS. 1 to 4, the plurality of memory dies may share one channel. That is, one channel may sequentially transfer commands to memory dies coupled to the channel, or sequentially transfer data from the memory dies to the controller 130.

With the increase in capacity of the memory system 110, the number of memory dies coupled to one channel may be increased. The more the number of memory dies coupled to one channel, the longer the latency for a read request from the host 102. For example, when the controller 130 sequentially acquires data from memory dies coupled to a certain channel through the channel after page read operations of the memory dies are completed, the latency of the read request associated with data acquired for the last time may be increased.

When the controller 130 generates interleaved read commands based on read requests from the host 102, the read commands may be processed in an order different from the order in which read requests corresponding to the read commands are received from the host 102, i.e., a host-requested order.

For example, the controller 130 may adjust the order of the read requests such that read operations can be simultaneously performed in as many memory dies as possible, and generate interleaved read commands based on the read requests whose order has been adjusted. The controller 130 may include a plurality of command queues provided for the respective memory dies. The controller 130 may divide and queue the interleaved read commands into a plurality of command queues, and provide the memory device 150 with the read commands in a predetermined order, regardless of the host-requested order.

When the host-requested order cannot be considered when the controller 130 controls a data output operation of the memory device 150 based on the read commands, the case in which data for a read request which was received early from the host 102 among the read requests is acquired later may occur. When the data for the early-received read request is acquired later, the quality of service (QoS) required for the request may not be satisfied.

In accordance with an embodiment, the controller 130 may generate order information indicating a host-requested order of read requests, and generate interleaved read commands based on the read requests. The controller 130 may control a plurality of memory dies to perform page read operations at the same time in response to the interleaved read commands. When the page read operations are completed, the controller 130 may provide data output commands to the plurality of memory dies according to an order decided by referring to the host-requested order information. The controller 130 may acquire data, buffered in page buffers PBs of the plurality of memory dies, according to the host-requested order, and provide the host 102 with responses to the read requests according to the order in which the data are acquired.

In accordance with an embodiment, even when the processing order of the read requests is adjusted, the controller 130 may control data output operations of the plurality of memory dies according to the host-requested order of the read requests. That is, the controller 130 may first acquire data for an early-received read request from the memory device 150, and provide the acquired data to the host 102. The controller 130 may first provide the host 102 with the data for the early-received read request, thereby reducing the latency of the read requests and satisfying the QoS required for the read requests. Therefore, the throughput of the memory system 110 may be improved.

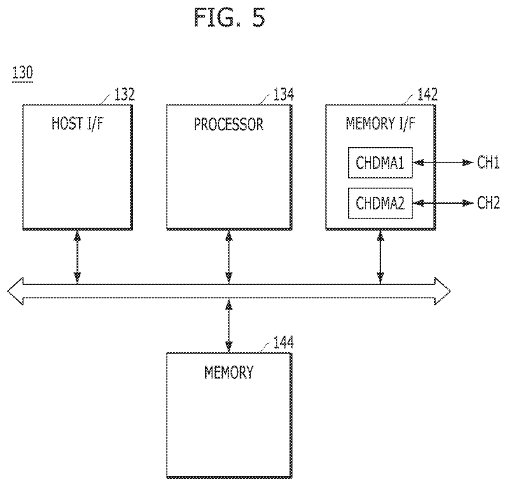

Embodiments of the present disclosure will be described in detail with reference to FIGS. 5 to 9.

FIG. 5 is a diagram illustrating the architecture of the controller 130 in accordance with embodiments of the present disclosure.

Referring to FIG. 5, the controller 130 may include a host interface (I/F) 132, a processor 134, a memory I/F 142, and a memory 144 all operatively coupled via an internal bus.

The host I/F 132 may be configured to process a command and data of the host 102, and may communicate with the host 102 through one or more of various communication standards or interfaces such as universal serial bus (USB), multi-media card (MMC), peripheral component interconnect-express (PCI-e or PCIe), small computer system interface (SCSI), serial-attached SCSI (SAS), serial advanced technology attachment (SATA), parallel advanced technology attachment (PATA), enhanced small disk interface (ESDI) and integrated drive electronics (IDE). The host I/F 132 may be driven through firmware referred to as a host interface layer (HIL) in order to exchange data with the host.

The host I/F 132 may include a request queue. The host I/F 132 may queue requests from the host 102 into the request queue according to the order in which the requests are received. The host I/F 132 may provide the processor 134 with the requests queued in the request queue.

The processor 134 may control the overall operations of the memory system 110. The processor 134 may drive firmware to control the overall operations of the memory system 110. The firmware may be referred to as flash translation layer (FTL). Also, the processor 134 may be realized as a microprocessor or a central processing unit (CPU).

The processor 134 may drive the FTL and perform a foreground operation corresponding to a request received from the host 102. For example, the processor 134 may control a write operation of the memory device 150 in response to a write request from the host 102 and control a read operation of the memory device 150 in response to a read request from the host 102.

The processor 134 may map the logical address of a request, received from the host I/F 132, to a physical address of the memory device 150. The processor 134 may translate a write request, a read request and an erase request into a program command, a read command and an erase command for the memory device 150, respectively. In an implementation, the processor 134 may adjust the order of write requests and thus maximize the one-shot program throughput, one-shot read throughput or parallel processing throughput of the memory device 150. Similarly, the processor 134 may adjust the order of read requests based on physical addresses corresponding to the read requests, and translate the read requests into read commands based on the adjusted order, thereby generating the interleaved read commands.

In accordance with the present embodiment, the processor 134 may provide the host-requested order of the read commands to the memory I/F 142 together, while providing the interleaved read commands to the memory I/F 142.

Also, the controller 130 may perform a background operation onto the memory device 150 through the processor 134, which is realized as a microprocessor or a CPU. For example, the background operation performed onto the memory device 150 may include a garbage collection (GC) operation, a wear-leveling (WL) operation, a map flush operation, or a bad block management operation.

The memory I/F 142 may serve as a memory/storage interface for interfacing the controller 130 and the memory device 150 such that the controller 130 controls the memory device 150 in response to a request from the host 102. When the memory device 150 is a flash memory, specifically, a NAND flash memory, the memory I/F 142 may generate a control signal for the memory device 150 and process data to be provided to the memory device 150 under the control of the processor 134. The memory I/F 142 may work as an interface (e.g., a NAND flash interface) for processing a command and data between the controller 130 and the memory device 150. Specifically, the memory I/F 142 may support data transfer between the controller 130 and the memory device 150. The memory I/F 142 may be driven through firmware referred to as a flash interface layer (FIL) in order to exchange data with the memory device 150.

The memory I/F 142 may control the memory device 150 in response to a command received from the processor 134.

The memory I/F 142 may include channel direct memory accesses (DMAs) CHDMA1 and CHDMA2. The channel DMAs CHDMA1 and CHDMA2 may provide commands to the memory device 150 through channels CH1 and CH2 without intervention of the processor 134, and perform data input/output operations between the controller 130 and the memory device 150.

In accordance with an embodiment, the memory I/F 142 may acquire interleaved read commands and the host-requested order of the interleaved read commands from the processor 134 together. The memory I/F 142 may control the memory device 150 such that page read operations corresponding to the interleaved read commands can be performed in a plurality of memory dies at the same time. When the page read operations corresponding to the read commands are completed, the memory I/F 142 may provide the memory device 150 with data output commands corresponding to the read commands based on the host-requested order. The channel DMAs CHDMA1 and CHDMA2 may buffer data chunks into the memory 144, the data chunks being outputted from the memory device 150 in the host-requested order.

The memory 144 may serve as a working memory of the memory system 110 and the controller 130, and store data for driving the memory system 110 and the controller 130. The controller 130 may control the memory device 150 to perform read, program and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by a static random access memory (SRAM) or a dynamic random access memory (DRAM). The memory 144 may be disposed within or out of the controller 130. By way of example, FIG. 1 illustrates the memory 144 disposed within the controller 130. Alternatively, the memory 144 may be embodied by an external volatile memory having a memory interface transferring data between the memory 144 and the controller 130.

In accordance with an embodiment, the host I/F 132 may provide the data chunks buffered in the memory 144 to the host 102 according to the host-requested order. Therefore, the memory system 110 in accordance with an embodiment may provide the improved QoS for the read requests from the host 102.

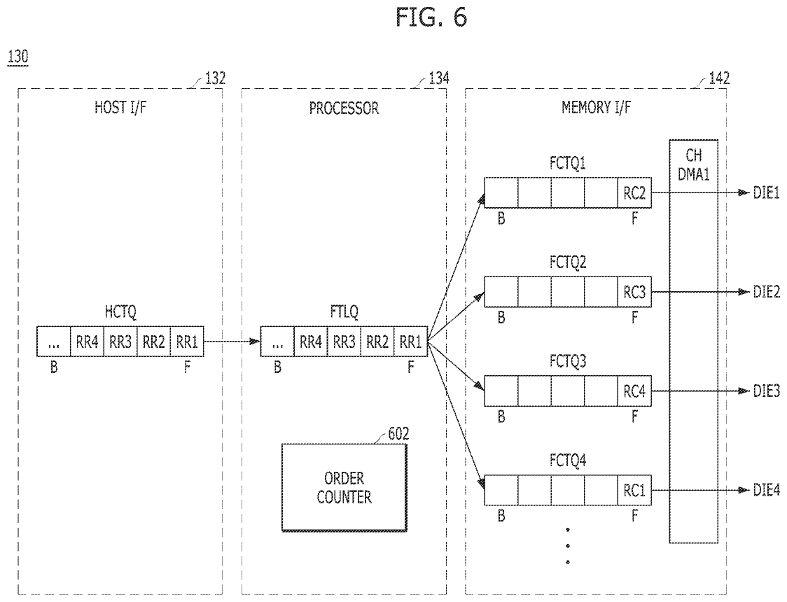

Hereafter, embodiments of the present disclosure will be described in detail with reference to FIGS. 6 to 9.

FIG. 6 is a diagram for describing a controller 130 in accordance with a first embodiment of the present disclosure.

Referring to FIG. 6, the controller 130 includes a host I/F 132, a processor 134 and a memory I/F 142. The host I/F 132, the processor 134 and the memory I/F 142, which are illustrated in FIG. 6, correspond to those described with reference to FIG. 5.

The host I/F 132 may include a host controller (HCT) queue HCTQ capable of queuing requests from a host 102. The HCT queue HCTQ may queue the requests from the host 102 in a host-requested order, and provide the queued requests to the processor 134 according to the order in which the requests are queued. FIG. 6 illustrates the back B of the HCT queue HCTQ, into which requests from the host 102 are queued, and the front F of the HCT queue HCTQ, from which the queued requests are outputted. FIG. 6 illustrates the state in which a plurality of read requests from the host 102 are received in order of a first read request RR1, a second read request RR2, a third read request RR3 and a fourth read request RR4, and queued in the HCT queue HCTQ according to the order in which the read requests are received.

The processor 134 may include an FTL queue FTLQ capable of queuing the requests from the HCT queue HCTQ. The FTL queue FTLQ may sequentially queue the requests according to the order in which the requests are received from the HCT queue HCTQ. FIG. 6 illustrates the state in which the read requests RR1 to RR4 from the HCT queue HCTQ are queued in the FTL queue FTLQ.

FIG. 6 illustrates the case in which requests are queued in one FTL queue FTLQ regardless of the priorities of the requests. Since the requests are first inputted to and first outputted from the HCT queue HCTQ, the read requests RR1 to RR4 from the HCT queue HCTQ may be queued in the FTL queue FTLQ in the same order as the host-requested order.

The processor 134 may generate read commands RC1 to RC4 based on the read requests RR1 to RR4 queued in the FTL queue FTLQ. The processor 134 may translate the logical addresses of the read requests RR1 to RR4 into physical addresses for the read commands RC1 to RC4.

The processor 134 may adjust the order of the read requests RR1 to RR4 based on the physical addresses, and generate interleaved read commands based on the adjusted order. In the example of FIG. 6, the first read request RR1 may be processed in the fourth memory die DIE4, the second read request RR2 may be processed in the first memory die DIE1, the third read request RR3 may be processed in the second memory die DIE2, and the fourth read request RR4 may be processed in the third memory die DIE3. The processor 134 may provide the memory I/F 142 with the read commands RC1 to RC4 corresponding to the read requests RR1 to RR4 in order of the second read command RC2, the third read command RC3, the fourth read command RC4 and the first read command RC1.

The memory I/F 142 may include a plurality of flash controller (FCT) queues FCTQ. Each of the FCT queues may correspond to one memory die. By way of example, FIG. 6 illustrates only first to fourth FCT queues FCTQ1 to FCTQ4 corresponding to the first to fourth memory dies DIE1 to DIE4.

The memory I/F 142 may sequentially queue the second read command RC2, the third read command RC3, the fourth read command RC4 and the first read command RC1 into first to fourth FCT queues FCTQ1 to FCTQ4.

In accordance with an embodiment, the processor 134 may provide the memory I/F 142 with the read commands RC1 to RC4 and the host-requested order of the read commands RC1 to RC4 together, such that the memory I/F 142 can identify the host-requested order of the read commands whose order is adjusted and which are queued in different FCT queues.

The processor 134 may include a first order counter 602 to determine the host-requested order through a count operation. For example, the processor 134 may update the count whenever a read request is queued in the FTL queue FTLQ, determine the host-requested order for the read request using the updated count value and provide the host-requested order for the read request to the memory I/F 142.

The memory I/F 142 may provide page read commands to the first to fourth memory dies DIE1 to DIE4 through a first channel CH1, such that the first to fourth memory dies DIE1 to DIE4 perform page read operations at the same time in response to the read commands RC1 to RC4 queued in the first to fourth FCT queues FCTQ1 to FCTQ4.

When the page read operations of the first to fourth memory dies DIE1 to DIE4 are completed, the memory I/F 142 may provide the first to fourth memory dies DIE1 to DIE4 with data output commands corresponding to the read commands RC1 to RC4 based on the host-requested order.

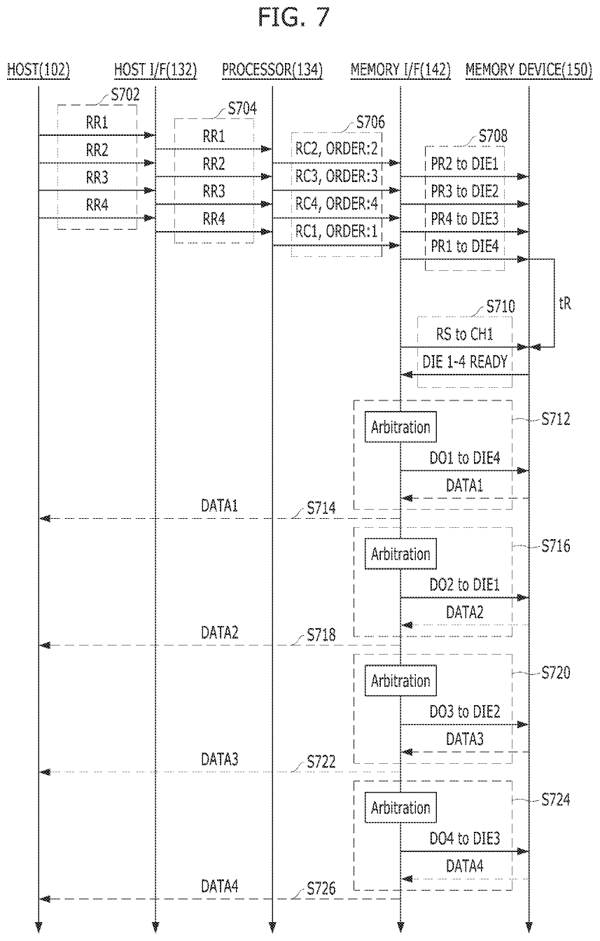

FIG. 7 is a diagram illustrating an operation of a data processing system 100 in accordance with a first embodiment of the present disclosure.

A host 102, a host I/F 132, a processor 134, a memory I/F 142 and a memory device 150, which are illustrated in FIG. 7, correspond to those described with reference to FIGS. 1 to 6.

In operation S702, the host 102 may sequentially provide read requests RR1 to RR4 to the host I/F 132. The host I/F 132 may queue the read requests RR1 to RR4 into the HCT queue HCTQ.

In operation S704, the host I/F 132 may sequentially provide the read requests RR1 to RR4, queued in the HCT queue HCTQ, to the processor 134. The processor 134 may queue the read requests RR1 to RR4 into the FTL queue FTLQ. The processor 134 may translate the logical addresses of the read requests RR1 to RR4 into physical addresses, and generate interleaved read commands RC1 to RC4 based on the physical addresses. The processor 134 may adjust the order of the read requests RR1 to RR4 in order to generate the interleaved read commands RC1 to RC4. The processor 134 may generate host-requested order information on each of the read requests RR1 to RR4 before adjusting the order of the read requests RR1 to RR4.

In operation S706, the processor 134 may provide the memory I/F 142 with the interleaved read commands RC1 to RC4 and the host-requested order information corresponding to each of the read commands RC1 to RC4. The memory I/F 142 may queue the read commands RC1 to RC4, received from the processor 134, into the corresponding FCT queues FCTQ.

In operation S708, the memory I/F 142 may provide page read commands PR1 to PR4 to the memory device 150 such that the page read operations can be simultaneously performed in a plurality of memory dies, based on the read commands RC1 to RC4 queued in the plurality of FCT queues FCTQ.

For example, page read commands which are to be performed at the same time may be provided to the memory device 150 in a set manner (e.g., a round-robin manner) according to the identifiers of the memory dies. In the example of FIG. 7, the read commands RC1 to RC4 may sequentially correspond to the page read commands PR1 to PR4. The page read commands may be provided to the memory device 150 in order of the second page read command PR2, the third page read command PR3, the fourth page read command PR4 and the first page read command PR1.

The first to fourth memory dies DIE1 to DIE4 may buffer a second data chunk DATA2, a third data chunk DATA3, a fourth data chunk DATA4 and a first data chunk DATA1 into the page buffers PB in response to the page read commands PR1 to PR4. The data chunks DATA1 to DATA4 may sequentially correspond to the read requests RR1 to RR4.

When a predetermined time tR has elapsed after the page read commands PR1 to PR4 were provided, the memory I/F 142 may provide a state read command to the memory device 150 in operation S710. FIG. 7 illustrates the case in which the state read command (RS to CH1) is provided to the first to fourth memory dies DIE1 to DIE4 through the first channel CH1 in order to check the states of the first to fourth memory dies DIE1 to DIE4.

The memory device 150 may provide the state information of the first to fourth memory dies DIE1 to DIE4 in response to the state read command. The state information may indicate whether each of the first to fourth memory dies DIE1 to DIE4 is in a ready or busy state. The ready state may indicate the state in which the page read operation of a memory die is completed, and the busy state may indicate the state in which the page read operation of a memory die is not completed. If there is a memory die in the busy state, the memory I/F 142 may periodically provide the state read command to the memory die until the state of the memory die is changed into the ready state. In the example of FIG. 7, the memory device 150 may provide status information indicating a ready state (DIE 1-4 READY) to the memory I/F 142.

In operation S712, the memory I/F 142 may decide (or arbitrate) to which memory die a data output command is to be first provided, among memory dies in the ready state, based on the host-requested order.

In the example of FIG. 7, all of the first to fourth memory dies DIE1 to DIE4 may be in the ready state. The command whose host-requested order is the earliest, among the read commands to be processed by the first to fourth memory dies DIE1 to DIE4, may be the first read command RC1. The memory I/F 142 may provide a first data output command DO1 to the fourth memory die DIE4 in order to acquire the first data chunk DATA1 corresponding to the first read command RC1. The first channel DMA CHDMA1 of the memory I/F 142 may acquire the first data chunk DATA1, outputted in response to the first data output command DO1, from the fourth memory die DIE4.

In operation S714, the first channel DMA CHDMA1 may buffer the acquired first data chunk DATA1 into the memory 144. The host I/F 132 may provide the host 102 with the first data chunk DATA1 buffered in the memory 144.

In operation S716, the memory I/F 142 may decide to which memory die an output command is to be first provided, among memory dies which are in the ready state and where data output operations are not yet performed, based on the host-requested order.

In the example of FIG. 7, the command whose host-requested order is the earliest, among the second to fourth read commands RC2 to RC4 to be processed by the first to third memory dies DIE1 to DIE3 where data output operations are not yet performed, may be the second read command RC2. The memory I/F 142 may provide a second data output command D02 to the first memory die DIE1 in order to acquire the second data chunk DATA2 corresponding to the second read command RC2. The first channel DMA CHDMA1 may acquire the second data chunk DATA2 outputted from the first memory die DIE1.

In operation S718, the first channel DMA CHDMA1 may buffer the acquired second data chunk DATA2 into the memory 144. The host I/F 132 may provide the host 102 with the second data chunk DATA2 buffered in the memory 144.

In operations S720 and S722, the memory I/F 142 may acquire the third data chunk DATA3 from the second memory die DIE2 and buffer the acquired third data chunk DATA3 into the memory 144, and the host I/F 132 may provide the host 102 with the third data chunk DATA3 buffered in the memory 144.

In operations S724 and S726, the memory I/F 142 may acquire the fourth data chunk DATA4 from the third memory die DIE3 and buffer the acquired fourth data chunk DATA4 into the memory 144, and the host I/F 132 may provide the host 102 with the fourth data chunk DATA4 buffered in the memory 144.

The operations S720, S722, S724 and S726 may be performed in a similar manner to that described with reference to operations S712, S714, S716 and S718.

In accordance with the first embodiment, the memory I/F 142 may acquire data chunks from the memory dies where page read operations have been performed based on read commands interleaved in an order different from the host-requested order, based on the host-requested order acquired from the processor 134. The controller 130 may not wait for a data chunk, requested later from the host 102, to be outputted from the memory device 150, but acquire an early-requested data chunk from the memory device 150 and preferentially provide the early-requested data chunk to the host 102. Therefore, the memory system 110 may provide rapid responses to the read requests of the host 102.

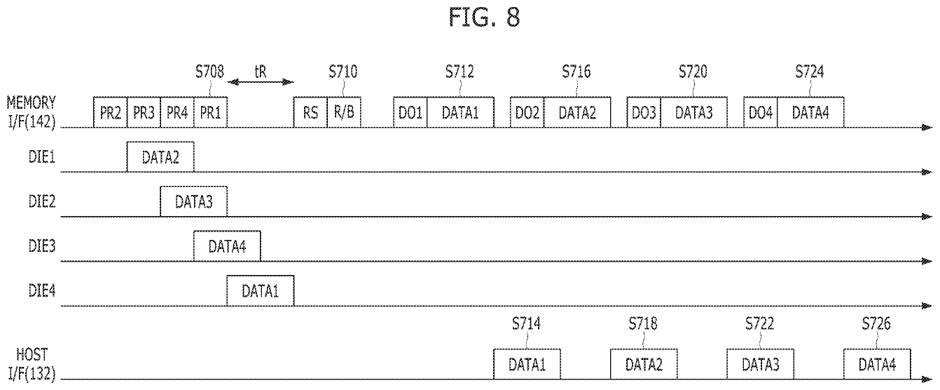

FIG. 8 is a timing diagram for describing an operation of the memory system 110 in accordance with the first embodiment of the present disclosure.

Specifically, FIG. 8 illustrates the operation timings of the host I/F 132, the first to fourth memory dies DIE1 to DIE4 and the memory I/F 142, which perform the operation described with reference to operations S708, S710, S712, S714, S716, S718, S720, S722, S724 and S726 of FIG. 7.

Referring to FIG. 8, the memory I/F 142 may provide the second page read command PR2, the third page read command PR3, the fourth page read command PR4 and the first page read command PR1 to the first to fourth memory dies DIE1 to DIE4, respectively, based on the interleaved read commands RC1 to RC4, in operation S708.

The first to fourth memory dies DIE1 to DIE4 may buffer the second data chunk DATA2, the third data chunk DATA3, the fourth data chunk DATA4 and the first data chunk DATA1 into the page buffers PB by performing page read operations in response to the page read commands from the memory I/F 142.

In operation S710, the memory I/F 142 may check that the page read operations of the first to fourth memory dies DIE1 to DIE4 are completed. When the page read operations are completed, the memory I/F 142 may acquire the data chunks DATA1 to DATA4 from the memory device 150 according to the host-requested order, and the host I/F 132 may provide the acquired data chunks DATA1 to DATA4 to the host 102, in operations S712, S710, S712, S714, S716, S718, S720, S722, S724 and S726. As Illustrated in FIG. 8, an operation of the memory I/F 142 in operations S712, S716, S720 and S724 may be performed in parallel to an operation of the host I/F 132 in operations S714, S718, S722 and S726.

For example, the first data chunk DATA1 may be data that corresponds to the first read request RR1 and has been first requested from the host 102. The controller 130 may not wait for the second to fourth data chunks DATA2 to DATA4 to be outputted, but first acquire the first data chunk DATA1 from the memory device 150 and provide the acquired first data chunk DATA1 to the host 102. The controller 130 may acquire the second data chunk DATA2 from the memory device 150 while providing the first data chunk DATA1 to the host 102. Similarly, the controller 130 may sequentially provide the second to fourth data chunks DATA2 to DATA4 to the host 102.

The first embodiment in which the processor 134 includes one FTL queue FTLQ has been described with reference to FIGS. 6 to 8. However, the present disclosure may also be applied to the case in which the processor 134 includes a plurality of FTL queues FTLQ. For example, the processor 134 may queue read requests, received from the HCT queue HCTQ, into different FTL queues FTLQ according to the priorities of the respective requests. The host I/F 132 may decide the priorities of the read requests, adjust the order of the read requests according to the priorities, and provide the read requests to the processor 134 in the adjusted order.

The processor 134 receiving the read requests provided in the adjusted order cannot determine the host-requested order of the read requests, only based on the order in which the read requests are queued into the respective FTL queues FTLQ.

In accordance with a second embodiment, the host I/F 132 may provide a host-requested order to the processor 134 together while providing read requests to the processor 134, such that the processor 134 can transfer the host-requested order to the memory I/F 142 together while providing interleaved read commands to the memory I/F 142. The memory I/F 142 may first acquire a data chunk which has been first requested from the host 102, among data chunks corresponding to the interleaved read commands, from the memory device 150 based on the host-requested order transferred from the processor 134.

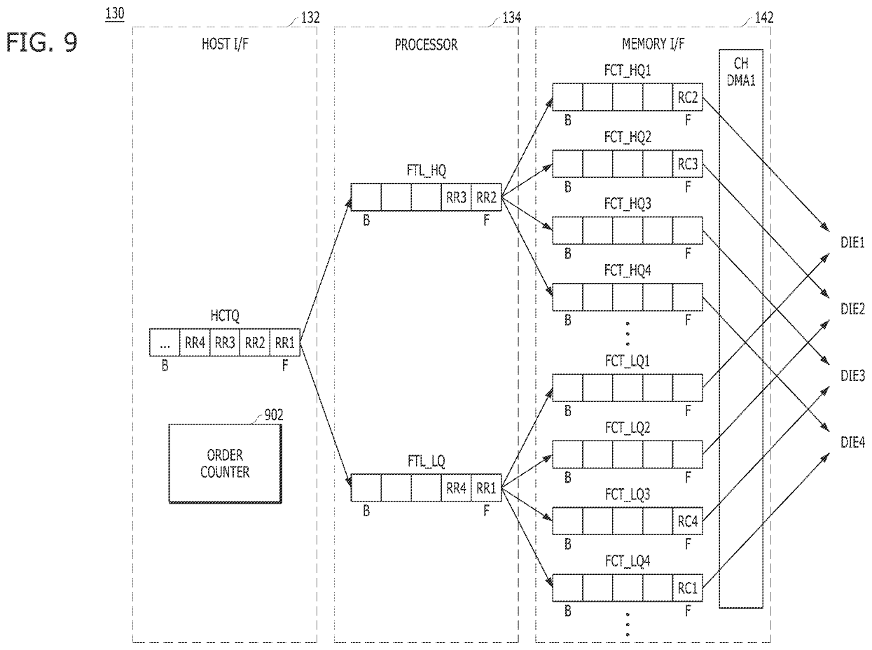

FIG. 9 is a diagram for describing a controller 130 in accordance with a second embodiment of the present disclosure.

The embodiment of FIG. 9 is different from the first embodiment of FIG. 6 in that the embodiment of FIG. 9 further includes queues based on the priorities of requests and commands. Thus, the following descriptions will be focused on the differences, and for the descriptions and reference numerals of components corresponding to the components of the first embodiment, those of the components of the first embodiment may be quoted.

FIG. 9 illustrates the host I/F 132, the processor 134 and the memory I/F 142, which are included in the controller 130. The host I/F 132, the processor 134 and the memory I/F 142, which are illustrated in FIG. 9, correspond to those described with reference to FIG. 5.

The HCT queue HCTQ of the host I/F 132 may queue the requests from the host 102 in a host-requested order, and provide the queued requests to the processor 134 according to the order in which the requests are queued.

In accordance with the second embodiment, the host I/F 132 may include a second order counter 902 configured to count the host-requested order. The second order counter 902 may update the count whenever a read request is received from the host 102, and provide the updated count as the host-requested order to the processor 134.

The host I/F 132 may queue a request from the host 102 into a request queue, and decide the priority of the request according to the characteristic of the request. The host I/F 132 may adjust the order of requests such that a request having a higher priority is processed before a request having a lower priority. The host I/F 132 may provide the requests to the processor 134 according to the adjusted order.

The processor 134 may include an FTL high queue FTL_HQ and an FTL low queue FTL_LQ. The processor 134 may queue read requests provided from the host I/F 132 into different FTL queues based on the priorities of the read requests. For example, read requests each having a relatively high priority may be queued into the FTL high queue FTL_HQ, and read requests each having a relatively low priority may be queued into the FTL low queue FTL_LQ. FIG. 9 illustrates the case in which the second read request RR2 and the third read request RR3 are queued into the FTL high queue FTL_HQ, and the first read request RR1 and the fourth read request RR4 are queued into the FTL low queue FTL_LQ.

The processor 134 may process the requests queued in the FTL high queue FTL_HQ before the requests queued in the FTL low queue FTL_LQ. For example, when read requests are queued in both of the FTL high queue FTL_HQ and the FTL low queue FTL_LQ, the processor 134 may generate interleaved read commands based on the read requests of the FTL high queue FTL_HQ, and provide the interleaved read commands to the memory I/F 142. Then, the processor 134 may generate interleaved read commands based on the read requests of the FTL low queue FTL_LQ, and provide the interleaved read commands to the memory I/F 142.

Whenever providing a read command to the memory I/F 142, the processor 134 may provide the host-requested order acquired from the host I/F 132 together.

The memory I/F 142 may include a plurality of FCT queues to separately queue read commands having different priorities for the respective memory dies. FIG. 9 illustrates FCT high queues FCT_HQ1 to FCT_HQ4 and FCT low queues FCT_LQ1 to FCT_LQ4, which correspond to the first to fourth memory dies DIE1 to DIE4.

The memory I/F 142 may queue read commands into an FCT queue which is decided based on the priorities and physical addresses of the read commands from the processor 134. FIG. 9 illustrates that the read commands RC1 to RC4 are divided and queued into the plurality of FCT queues according to the priorities and physical addresses thereof.

In accordance with the second embodiment, the memory I/F 142 may control the memory device 150 such that memory dies simultaneously perform page read operations in response to interleaved read commands, and acquire data chunks from memory dies in which the page read operations have been completed at the same time, according to the host-requested order. For example, the memory I/F 142 may first process the second and third read commands RC2 and RC3 queued in the FCT high queues FCT_HQ1 to FCT_HQ4 and then process the first and fourth read commands RC1 and RC4 queued in the FCT low queues FCT_LQ1 to FCT_LQ4. In order to process the third and fourth read commands RC3 and RC4, the memory I/F 142 may control the third and fourth memory dies DIE3 and DIE4 to perform page read operations at the same time. When the page read operations of the third and fourth memory dies DIE3 and DIE4 are completed, the memory I/F 142 may first acquire the first data chunk DATA1 from the fourth memory die DIE4, and then acquire the fourth data chunk DATA4 from the third memory die DIE3, based on the host-requested order.

In accordance with the embodiments of the present disclosure, the memory I/F 142 may acquire interleaved read commands and the host-requested order of the read commands from the processor 134, thereby performing data output operations corresponding to the read commands according to the host-requested order. The controller 130 may first acquire a data chunk, which has been first requested from the host 102, from the memory device 150, and provide the acquired data chunk to the host 102. Therefore, the memory system 110 may provide the host 102 with a high QoS for read requests.

The methods, processes, and/or operations described herein may be performed by code or instructions to be executed by a computer, processor, controller, or other signal processing device. The computer, processor, controller, or other signal processing device may be those herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods herein.

When implemented in at least partially in software, the controllers, processors, managers, devices, modules, units, multiplexers, generators, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

Although various embodiments have been described for illustrative purposes, it will be apparent to those skilled in the art that various changes and modifications may be made without departing from the spirit and scope of the invention as defined in the following claims. Furthermore, the embodiments may be combined to form additional embodiments.

What is claimed is:

1. A controller which controls a plurality of memory dies, the controller comprising:
a processor suitable for generating interleaved read commands based on read requests from a host;
a memory interface suitable for acquiring the read commands and a host-requested order of the read commands from the processor, controlling page read operations on the plurality of memory dies in response to the read commands, and acquiring data chunks corresponding to read requests from memory dies whose page read operations are completed, according to the host-requested order; and
a host interface suitable for providing the host with responses to the read requests according to the order in which the data chunks are acquired.

2. The controller of claim 1, wherein the operation of the memory interface to acquire the data chunks and the operation of the host interface to provide the responses to the read requests are performed in parallel.

3. The controller of claim 1, wherein the processor generates the read commands by adjusting a processing order of the read requests and translating the read requests into read commands according to the adjusted order.

4. The controller of claim 1, wherein the processor queues read requests from the host interface into a request queue, determines the order in which the read requests are queued, as a host-requested order, and provides the read requests and the host-requested order to the memory interface.

5. The controller of claim 1, wherein the memory interface comprises a plurality of command queues corresponding to the plurality of memory dies, and queues the read commands into the plurality of command queues based on memory dies in which the read commands are to be respectively processed.

6. The controller of claim 5, wherein the memory interface provides page read commands to the plurality of memory dies in a predetermined order according to identifiers of the plurality of memory dies, such that the page read operations of the plurality of memory dies are performed at the same time.

7. The controller of claim 6, wherein the memory interface provides a state read command to the memory dies when a predetermined time has elapsed after the page read commands are provided to the plurality of memory dies, and determines whether the page read operations are completed, based on responses of the memory dies to the state read command.

8. The controller of claim 1, wherein the host interface counts the host-requested order of the read requests, adjusts a processing order of the read requests based on the priorities of the read requests, and provides the processor with the host-requested order and the read requests whose processing order is adjusted.

9. The controller of claim 8, wherein the processor queues the read requests into a plurality of request queues based on the priorities, and provides the host-requested order from the host interface to the memory interface together when providing the memory interface with read commands queued in the plurality of request queues.

10. An operation method of a controller which controls a plurality of memory dies, the operation method comprising:
generating host-requested order information of read requests from a host based on the read requests;
generating interleaved read commands based on the read requests;
controlling page read operations on the plurality of memory dies based on the read commands;
acquiring data chunks corresponding to the read requests from memory dies whose page read operations are completed, according to the host-requested order; and
providing the host with responses to the read requests according to the order in which the data chunks are acquired.

11. The operation method of claim 10, wherein the acquiring the data chunks and the providing the host with the responses to the read requests are performed in parallel.

12. The operation method of claim 10, wherein the generating the read commands comprises:
adjusting a processing order of the read requests; and
translating the read requests into read commands according to the adjusted order.

13. The operation method of claim 10, further comprising:
queuing read requests from the host into a request queue; and
determining the order in which the read requests are queued, as the host-requested order.

14. The operation method of claim 10, further comprising queuing read commands into a plurality of command queues corresponding to the plurality of memory dies, based on memory dies in which the read commands are to be respectively processed.

15. The operation method of claim 14, wherein the controlling the page read operations comprises providing page read commands to the plurality of memory dies in a predetermined order according to the identifiers of the plurality of memory dies, such that the page read operations of the plurality of memory dies are performed at the same time.

16. The operation method of claim 15, further comprising:
providing a state read command to the memory dies when a predetermined time has elapsed after the page read commands were provided to the plurality of memory dies; and
determining whether the page read operations are completed, based on responses of the memory dies to the state read command.

17. The operation method of claim 10, further comprising adjusting the processing order of the read requests based on the priorities of the read requests,
wherein the adjusting the processing order is performed after the generating of the host-requested order information.

18. The operation method of claim 17, further comprising queuing the read requests into a plurality of request queues based on the priorities.

19. A system comprising:
a host; and
a memory system coupled to the host and including a controller and a plurality of dies coupled to the controller,
wherein the controller is configured to:
receive, from the host, a plurality of read requests;
generate interleaved read commands based on the plurality of read requests and order information indicating a requested order of the plurality of read requests;
control the plurality of memory dies to perform page read operations in response to the interleaved read commands;
receive data chunks from the plurality of memory dies based on the order information when the page read operations are completed; and
provide, to the host, the data chunks based on the order information.
